(19) United States
(12) Patent Application Publication
(10) Pub. No.: US 2026/0159947 A1
(43) Pub. Date: Jun. 11, 2026

(54) ORGANOMETALLIC COMPOUNDS, METHODS OF SYNTHESIZING ORGANOMETALLIC COMPOUNDS, and METHODS OF DEPOSITING METAL OXIDE FILMS and METAL NITRIDE FILMS

(71) Applicant: SEASTAR CHEMICALS ULC, Sidney (CA)

(72) Inventors: Shaun CEMBELLA, Victoria (CA); Diana FABULYAK, Victoria (CA); Cassidy CONOVER, Victoria (CA); Collin CAMPBELL, Sidney (CA); Wesley GRAFF, Singapore (SG)

(73) Assignee: SEASTAR CHEMICALS ULC, Sidney, BC (CA)

(21) Appl. No.: 19/408,853

(22) Filed: Dec. 4, 2025

Related U.S. Application Data
(60) Provisional application No. 63/728,333, filed on Dec. 5, 2024.

(51) Int. Cl. C23C 16/455; C07F 7/02; C23C 16/40

(52) U.S. Cl. CPC C23C 16/45553; C07F 7/025; C23C 16/40

(57) ABSTRACT

Disclosed herein are organometallic compounds including monomeric alkoxyaminosilane complexes and dimeric alkoxyaminosilane complexes useful as precursors for metal oxide and metal nitride vapor phase deposition. Additionally, disclosed herein are methods for synthesizing these organometallic compounds and methods for forming metal oxide films and metal nitride films by vapor phase deposition using these organometallic compounds.

### FIELD OF THE DISCLOSURE

The present disclosure relates to organometallic compounds, namely monomeric alkoxyaminosilane complexes and dimeric alkoxyaminosilane complexes, that may be useful as precursors for metal oxide and metal nitride vapor phase deposition. Additionally, the present disclosure relates to methods for synthesizing these organometallic compounds and methods for forming metal oxide films and metal nitride films by vapor phase deposition using these organometallic compounds.

### BACKGROUND OF THE DISCLOSURE

In the semiconductor industry, Moore's law demands delivery of N+1 node improvements in scaling and performance. However, as the size of transistors decreases, challenges arise with the use of standard methods for thermal deposition of metal oxides, such as silicon dioxide (SiO₂), and metal nitrides, such as silicon nitride (SiN), at high temperature. For example, the use of high temperature may cause diffusion of elements, which may change the basic properties of transistors. Consequently, devices may be damaged. Therefore, low temperature thermal deposition of high-quality metal oxides for high dielectric constant (k) applications is preferred. Accordingly, atomic layer deposition (ALD) methods for the deposition of metal oxide films and metal nitride films have been explored due to the lower process temperatures relative to chemical vapor deposition (CVD).

Silicon dioxide and silicon nitride are common dielectric materials in silicon microelectronic devices. Heretofore, precursors for SiO₂ and SiN vapor phase deposition have been synthesized using pyrophoric reagents, such as lithium amide salts. During the synthesis process, these lithium amide salts may form flammable byproduct salts. Accordingly, the synthesis and manufacturing processes for these precursors are dangerous and present environmental concerns. Affordability of starting materials is also a concern.

Thus, there are needs in the industry for precursors for the deposition of high-quality metal oxide and metal nitride films via vapor phase deposition processes as well as safer synthesis and manufacturing processes for these precursors, including safer, more affordable and sustainable starting materials.

### SUMMARY OF THE DISCLOSURE

In consideration of the foregoing needs in the industry, the present disclosure provides organometallic compounds including monomeric alkoxyaminosilane complexes and dimeric alkoxyaminosilane complexes that may be useful as precursors for SiO₂ and SiN vapor phase deposition, chemical syntheses for these organometallic compounds, and methods for forming SiO₂ and SiN films by vapor phase deposition, including chemical vapor deposition (CVD), plasma enhanced chemical vapor deposition (PECVD), atomic layer deposition (ALD), and plasma enhanced atomic layer deposition (PEALD), using these organometallic compounds.

In one aspect, the present disclosure provides a method of synthesizing an organometallic compound of Formula I:

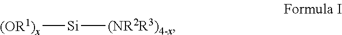

R¹, R², and R³ are independently selected from the group consisting of H and an acyclic or a cyclic alkyl group having from 1 to 10 carbon atoms, and
x is an integer from 1 to 3, comprising:
(A) loading a reactor with a solvent and SiCl₄,
(B) adding at least one equivalent of an alcohol of HOR¹ to the reactor,
(C) adding at least two equivalents of HNR²R³ to the reaction to yield a Cl⁻[H₂NR²R³]⁺ salt byproduct,
(D) removing the Cl⁻[H₂NR²R³]⁺ salt byproduct by filtration, and
(E) purifying the organometallic compound of Formula I by distillation.

In embodiments thereof, the method may further include a step of cooling the reactor after loading the reactor with solvent and SiCl₄.

In embodiments thereof, the method may further include a step of heating the reactor after adding at least one equivalent of an alcohol of HOR¹ to the reactor.

In embodiments thereof, the solvent may be selected from the group consisting of a hydrocarbon solvent selected from saturated aliphatic hydrocarbons, unsaturated aliphatic hydrocarbons having one or more carbon-carbon double or triple bonds, cyclic hydrocarbons (including cycloalkanes and cycloalkenes), and aromatic hydrocarbons, each having up to 60 carbon atoms, and mixtures thereof. Optionally, the solvent may include one or more atoms from group 14, 15, and 16.

In embodiments thereof, R¹, R², and R³ may be acyclic alkyl groups having from 1 to 4 carbon atoms.

In embodiments thereof, R¹ may be methyl or ethyl.

In embodiments thereof, R², and R³ may be methyl or ethyl.

In embodiments thereof, R², and R³ may be different.

In embodiments thereof, x may be 2.

In another aspect, the present disclosure provides an organometallic compound of Formula II:

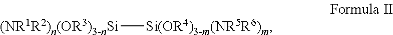

wherein
R¹, R², R³, R⁴, R⁵, and R⁶ are independently selected from the group consisting of H and an acyclic or a cyclic alkyl group having from 1 to 10 carbon atoms, and
n is an integer from 0 to 3 and m is an integer from 1 to 3.

In embodiments thereof, R¹, R², R³, R⁴, R⁵, and R⁶ may be acyclic alkyl groups having from 1 to 4 carbon atoms.

In embodiments thereof, R³ and R⁴ may be isopropyl.

In embodiments thereof, R¹, R², R³, and R⁴ may be methyl or ethyl.

In embodiments thereof, R¹ and R² may be different, and R³ and R⁴ may be different.

In embodiments thereof, m and n may be 2.

In another aspect, the present disclosure provides an organometallic compound of Formula III:

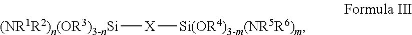

wherein
R¹, R², R³, R⁴, R⁵, and R⁶ are independently selected from the group consisting of H and an acyclic or a cyclic alkyl group having from 1 to 10 carbon atoms,
n is an integer from 0 to 3 and m is an integer from 1 to 3,
X is selected from the group consisting of O, NR⁷, CO, COO, CO(CR⁷R⁸)_{y}, and (CR⁷R⁸)_{y},
R⁷ and R⁸ are independently selected from the group consisting of H and an acyclic or a cyclic alkyl group having from 1 to 10 carbon atoms, and
y is an integer from 1 to 6.

In embodiments thereof, R¹, R², R³, R⁴, R⁵, and R⁶ may be acyclic alkyl groups having from 1 to 4 carbon atoms.

In embodiments thereof, R¹, R², R³, and R⁴ may be methyl or ethyl.

In embodiments thereof, R¹ and R² may be different, and R³ and R⁴ may be different.

In embodiments thereof, m and n may be 2.

In embodiments thereof, X may be selected from the group consisting of O, NR⁷, CO.

In another aspect thereof, the present disclosure provides a method of forming a metal oxide film or a metal nitride film by a vapor phase deposition process, which may include:
(A) providing at least one substrate having functional O—H groups covering the surface,
(B) delivering to said substrate at least one compound of Formula II in the gaseous phase:

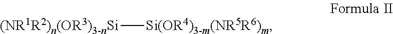

wherein
R¹, R², R³, R⁴, R⁵, and R⁶ are independently selected from the group consisting of H and an acyclic or a cyclic alkyl group having from 1 to 10 carbon atoms, and
n is an integer from 0 to 3 and m is an integer from 1 to 3,
(C) purging the substrate with purge gas,
(D) delivering to said substrate an oxygen source or a nitrogen source in the gaseous or plasma phase,
(E) purging the substrate with purge gas,
(F) repeating steps (B) through (E) until a desired thickness of metal oxide has been deposited.

In embodiments thereof, R¹, R², R³, R⁴, R⁵, and R⁶ may be acyclic alkyl groups having from 1 to 4 carbon atoms.

In embodiments thereof, R³ and R⁴ may be isopropyl.

In embodiments thereof, R¹, R², R³, and R⁴ may be methyl or ethyl.

In embodiments thereof, R¹ and R² may be different, and R³ and R⁴ may be different.

In embodiments thereof, m and n may be 2.

In another aspect thereof, the present disclosure provides a method of forming a metal oxide film or a metal nitride film by a vapor phase deposition process, which may include:
(A) providing at least one substrate having functional O—H groups covering the surface,
(B) delivering to said substrate at least one compound of Formula III in the gaseous phase:

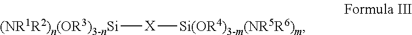

wherein
R¹, R², R³, R⁴, R⁵, and R⁶ are independently selected from the group consisting of H and an acyclic or a cyclic alkyl group having from 1 to 10 carbon atoms,
n is an integer from 0 to 3 and m is an integer from 1 to 3,
X is selected from the group consisting of O, NR⁷, CO, COO, CO(CR⁷R⁸)_{y}, and (CR⁷R⁸)_{y},
R⁷ and R⁸ are independently selected from the group consisting of H and an acyclic or a cyclic alkyl group having from 1 to 10 carbon atoms, and
y is an integer from 1 to 6,
(C) purging the substrate with purge gas,
(D) delivering to said substrate an oxygen source or a nitrogen source in the gaseous or plasma phase,
(E) purging the substrate with purge gas,
(F) repeating steps (B) through (E) until a desired thickness of metal oxide has been deposited.

In embodiments thereof, R¹, R², R³, R⁴, R⁵, and R⁶ may be acyclic alkyl groups having from 1 to 4 carbon atoms.

In embodiments thereof, R¹, R², R³, and R⁴ may be methyl or ethyl.

In embodiments thereof, R¹ and R² may be different, and R³ and R⁴ may be different.

In embodiments thereof, m and n may be 2.

In embodiments thereof, X may be selected from the group consisting of O, NR⁷, CO.

In another aspect, the present disclosure provides a method of synthesizing an organometallic compound of Formula II:

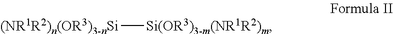

wherein
R¹, R², and R³ are independently selected from the group consisting of H and an acyclic or a cyclic alkyl group having from 1 to 10 carbon atoms, and
n is an integer from 0 to 3 and m is an integer from 1 to 3, comprising:
(A) loading a reactor with a solvent and Si₂Cl₆,
(B) adding at least one equivalent of an alcohol of HOR³ to the reactor,
(C) adding at least two equivalents of HNR¹R² to the reaction to yield a Cl⁻[H₂NR¹R²]⁺ salt byproduct,
(D) removing the Cl⁻[H₂NR¹R²]⁺ salt byproduct by filtration, and
(E) purifying the organometallic compound of Formula II by distillation.

In embodiments thereof, R¹, R², R³, R⁴, R⁵, and R⁶ may be acyclic alkyl groups having from 1 to 4 carbon atoms.

In embodiments thereof, R³ and R⁴ may be isopropyl.

In embodiments thereof, R¹, R², R³, and R⁴ may be methyl or ethyl.

In embodiments thereof, R¹ and R² may be different, and R³ and R⁴ may be different.

In embodiments thereof, m and n may be 2.

In another aspect, the present disclosure provides a method of synthesizing an organometallic compound of Formula III:

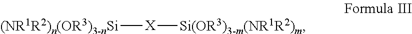

wherein
R¹, R², and R³ are independently selected from the group consisting of H and an acyclic or a cyclic alkyl group having from 1 to 10 carbon atoms,
n is an integer from 0 to 3 and m is an integer from 1 to 3,
X is selected from the group consisting of O, NR⁴, CO, COO, CO(CR⁴R⁵)_{y}, and (CR⁴R⁵)_{y},
R⁴ and R⁵ are independently selected from the group consisting of H and an acyclic or a cyclic alkyl group having from 1 to 10 carbon atoms, and
y is an integer from 1 to 6, comprising:
(A) loading a reactor with a solvent and Cl₃Si—X—SiCl₃,
(B) adding at least one equivalent of an alcohol of HOR³ to the reactor,
(C) adding at least two equivalents of HNR¹R² to the reaction to yield a Cl⁻[H₂NR¹R²]⁺ salt byproduct,
(D) removing the Cl⁻[H₂NR¹R²]⁺ salt byproduct by filtration, and
(E) purifying the organometallic compound of Formula III by distillation.

In embodiments thereof, R¹, R², R³, R⁴, R⁵, and R⁶ may be acyclic alkyl groups having from 1 to 4 carbon atoms.

In embodiments thereof, R¹, R², R³, and R⁴ may be methyl or ethyl.

In embodiments thereof, R¹ and R² may be different, and R³ and R⁴ may be different.

In embodiments thereof, m and n may be 2.

In embodiments thereof, X may be selected from the group consisting of O, NR⁷, CO.

The foregoing and other features of the present disclosure and advantages of the disclosure will become more apparent in light of the following detailed description and with reference to the accompanying drawings. As will be realized, the present disclosure is capable of modifications in various aspects, all without departing from the scope of the disclosure. The description and drawings are illustrative in nature and not restrictive.

### BRIEF DESCRIPTION OF THE DRAWINGS

Embodiments of the present disclosure will now be described by way of example with reference to the accompanying drawings, of which:

FIG. 1 is a chromatogram of (iPrO)₂Si(NEt₂)₂;

FIG. 2 is a mass spectrum of (iPrO)₂Si(NEt₂)₂;

FIG. 3 is a chromatogram of (MeO)₃Si(NEt₂);

FIG. 4 is a mass spectrum of (MeO)₃Si(NEt₂);

FIG. 5 is a chromatogram of (EtO)₂Si(NEt₂)₂;

FIG. 6 is a mass spectrum of (EtO)₂Si(NEt₂)₂;

FIG. 7 is a chromatogram of (MeO)₃Si(N(iPr)₂);

FIG. 8 is a mass spectrum of (MeO)₃Si(N(iPr)₂);

FIG. 9 is a chromatogram of (iPrO)Si(NEtMe)₃;

FIG. 10 is a mass spectrum of (iPrO)Si(NEtMe)₃;

FIG. 11 is a chromatogram of (iPrO)₂(NEt₂)Si—Si(NEt₂)(OiPr)₂;

FIG. 12 is a mass spectrum of (iPrO)₂(NEt₂)Si—Si(NEt₂)(OiPr)₂; and

FIG. 13 is a schematic representation of an ALD system for thin film deposition.

### DETAILED DESCRIPTION

Before describing several exemplary embodiments, it is to be understood that the disclosure is not limited to the details of construction or process steps set forth in the following description. The disclosure is capable of other embodiments and of being practiced or being carried out in various ways.

Reference throughout this specification to “one embodiment,” “certain embodiments,” “one or more embodiments” or “an embodiment” means that a particular feature, structure, material, or characteristic described in connection with the embodiment is included in at least one embodiment. Thus, the appearances of the phrases such as “in one or more embodiments,” “in certain embodiments,” “in one embodiment” or “in an embodiment” in various places throughout this specification are not necessarily referring to the same embodiment. Furthermore, the particular features, structures, materials, or characteristics may be combined in any suitable manner in one or more embodiments.

Although reference herein is to particular embodiments, it is to be understood that these embodiments are merely illustrative of the principles and applications of the present disclosure. It will be apparent to those skilled in the art that various modifications and variations can be made to the compositions, method and apparatus of the present disclosure without departing from the spirit and scope of the disclosure. Thus, it is intended that the present disclosure include modifications and variations that are within the scope of the appended claims and their equivalents.

Reference throughout this specification to “a” or “an” represents one or more and is not limited to singular form, unless explicitly stated.

The following detailed description can be read in connection with the accompanying drawings in which like numerals designate like elements.

The present disclosure provides organometallic compounds, namely monomeric alkoxyaminosilane complexes of Formula I: (OR¹)ₓ—Si—(NR²R³)₄₋ₓ, and dimeric alkoxyaminosilane complexes of Formulas II: (NR¹R²)ₙ(OR³)₃₋ₙSi—Si(OR⁴)₃₋ₘ(NR⁵R⁶)ₘ and III: (NR¹R²)ₙ(OR³)₃₋ₙSi—X—Si(OR⁴)₃₋ₘ(NR⁵R⁶)ₘ, and methods of synthesizing these organometallic compounds. These monomeric and dimeric complexes may have utility as precursors for the deposition of SiO₂ and SiN via vapor phase deposition processes, such as chemical vapor deposition (CVD), plasma enhanced chemical vapor deposition (PECVD), atomic layer deposition (ALD), and plasma enhanced atomic layer deposition (PEALD). The organometallic compounds of Formulas I, II, and III are now described in detail.

For monomeric alkoxyaminosilane complexes of Formula I, i.e., (OR¹)ₓ—Si—(NR²R³)₄₋ₓ, R¹, R², and R³ may be H, acyclic (linear or branched) alkyl groups having from 1 to 10 carbon atoms, or cyclic alkyl groups having from 1 to 10 carbon atoms. The acyclic and/or cyclic alkyl groups may be saturated or unsaturated. In embodiments, R¹, R², and R³ may be alkyl groups having from 1 to 4 carbon atoms, such as methyl (Me), ethyl (Et), propyl (Pr), iso-propyl (iPr), n-butyl (nBu), tert-butyl (tBu), iso-butyl (iBr), or sec-butyl (sBu).

R¹, R², and R³ may be independently selected. In embodiments, R¹, R², and R³ may be the same. For example, R¹, R², and R³ may be methyl. Alternatively, R¹, R², and R³ may be different. For example, R¹ may be iso-propyl, and R² and R³ may be ethyl. Alternatively, for example, R¹ and R² may be methyl, and R³ may be ethyl.

For monomeric alkoxyaminosilane complexes of Formula I, i.e., (OR¹)ₓ—Si—(NR²R³)₄₋ₓ, X may be an integer from 1 to 3. As such, when x is 1, for example, compounds of Formula I have the general formula (OR¹)—Si—(NR²R³)₃. Alternatively, when x is 3, for example, compounds of Formula I may have the general formula (OR¹)₃—Si—(NR²R³).

Turning to dimeric alkoxyaminosilane complexes of Formula II, i.e., (NR¹R²)ₙ(OR³)₃₋ₙSi—Si(OR⁴)₃₋ₘ(NR⁵R⁶)ₘ, R¹, R², R³, R⁴, R⁵, and R⁶ may be H, acyclic (linear or branched) alkyl groups having from 1 to 10 carbon atoms, or cyclic alkyl groups having from 1 to 10 carbon atoms. The acyclic and/or cyclic alkyl groups may be saturated or unsaturated. In embodiments, R¹, R², R³, R⁴, R⁵, and R⁶ may be alkyl groups having from 1 to 4 carbon atoms, such as methyl, ethyl, propyl, iso-propyl, n-butyl, tert-butyl, iso-butyl, or sec-butyl.

R¹, R², R³, R⁴, R⁵, and R⁶ may be independently selected. In embodiments, R¹, R², R³, R⁴, R⁵, and R⁶ may be the same. For example, R¹, R², R³, R⁴, R⁵, and R⁶ may be methyl. R¹ and R² may be the same as R⁵ and R⁶. Similarly, R³ and R⁴ may be the same. Alternatively, R¹, R², R³, R⁴, R⁵, and R⁶ may be different. For example, R¹, R², R⁵, and R⁶ may be methyl, and R³ and R⁴ may be iso-propyl. Alternatively, for example, R¹ and R⁵ may be ethyl, R² and R⁶ may be methyl, and R³ and R⁴ may be methyl.

For dimeric alkoxyaminosilane complexes of Formula II, i.e., (NR¹R²)ₙ(OR³)₃₋ₙSi—Si(OR⁴)₃₋ₘ(NR⁵R⁶)ₘ, n may be an integer from 0 to 3 and m may be an integer from 1 to 3. As such, when m and n are 1, for example, compounds of Formula II may have the general formula (NR¹R²)(OR³)₂Si—Si(OR⁴)₂ (NR⁵R⁶). Alternatively, when m and n are 3, for example, compounds of Formula II may have the general formula (NR¹R²)₃Si—Si(NR⁵R⁶)₃. Dimeric alkoxyaminosilane complexes of Formula II may be asymmetrical, such as when n is 0 and m is 1. In such instances, compounds of Formula II may have the general formula (OR³)₃Si—Si(OR⁴)₂ (NR⁵R⁶).

Now turning to dimeric alkoxyaminosilane complexes of Formula III, i.e., (NR¹R²)ₙ(OR³)₃₋ₙSi—X—Si(OR⁴)₃₋ₘ(NR⁵R⁶)ₘ, R¹, R², R³, R⁴, R⁵, and R⁶ may be H, acyclic (linear or branched) alkyl groups having from 1 to 10 carbon atoms, or cyclic alkyl groups having from 1 to 10 carbon atoms. The acyclic and/or cyclic alkyl groups may be saturated or unsaturated. In embodiments, R¹, R², R³, R⁴, R⁵, and R⁶ may be alkyl groups having from 1 to 4 carbon atoms, such as methyl, ethyl, propyl, iso-propyl, n-butyl, tert-butyl, iso-butyl, or sec-butyl.

R¹, R², R³, R⁴, R⁵, and R⁶ may be independently selected. In embodiments, R¹, R², R³, R⁴, R⁵, and R⁶ may be the same. For example, R¹, R², R³, R⁴, R⁵, and R⁶ may be methyl. R¹ and R² may be the same as R⁵ and R⁶. Similarly, R³ and R⁴ may be the same. Alternatively, R¹, R², R³, R⁴, R⁵, and R⁶ may be different. For example, R¹, R², R⁵, and R⁶ may be methyl, and R³ and R⁴ may be iso-propyl. Alternatively, for example, R¹ and R⁵ may be ethyl, R² and R⁶ may be methyl, and R³ and R⁴ may be methyl.

For dimeric alkoxyaminosilane complexes of Formula III, i.e., (NR¹R²)ₙ(OR³)₃₋ₙSi—X—Si(OR⁴)₃₋ₘ (NR⁵R⁶)ₘ, n may be an integer from 0 to 3 and m may be an integer from 1 to 3. As such, when m and n are 1, for example, compounds of Formula II may have the general formula (NR¹R²)(OR³)₂Si—X—Si(OR⁴)₂ (NR⁵R⁶). Alternatively, when m and n are 3, for example, compounds of Formula II may have the general formula (NR¹R²)₃Si—X—Si(NR⁵R⁶)₃. Dimeric alkoxyaminosilane complexes of Formula III may be asymmetrical, such as when n is 0 and m is 1. In such instances, compounds of Formula III may have the general formula (OR³)₃Si—X—Si(OR⁴)₂ (NR⁵R⁶).

Additionally, for dimeric alkoxyaminosilane complexes of Formula III, i.e., (NR¹R²)ₙ(OR³)₃₋ₙSi—X—Si(OR⁴)₃₋ₘ(NR⁵R⁶)ₘ, X may be O, NR⁷, CO, COO, CO(CR⁷R⁸)_{y}, or (CR⁷R⁸)_{y}. When X is NR⁷, CO(CR⁷R⁸)_{y}, or (CR⁷R⁸)_{y}, R⁷ and R⁸ may be H, acyclic (linear or branched) alkyl groups having from 1 to 10 carbon atoms, or cyclic alkyl groups having from 1 to 10 carbon atoms. The acyclic and/or cyclic alkyl groups may be saturated or unsaturated. R⁷ and R⁸ may be alkyl groups having from 1 to 4 carbon atoms, such as methyl, ethyl, propyl, iso-propyl, n-butyl, tert-butyl, iso-butyl, or sec-butyl. Further, when X is CO(CR⁷R⁸)_{y}, or (CR⁷R⁸)_{y}, y may be an integer from 1 to 6. For example, X may be (CR⁷R⁸)_{y} and y may be 3, yielding a dimeric alkoxyaminosilane complex having the general formula (NR¹R²)ₙ(OR³)₃₋ₙSi—(CR⁷R⁸)₃—Si(OR⁴)₃₋ₘ(NR⁵R⁶)ₘ.

As introduced above, the present disclosure also provides methods of synthesizing the organometallic compounds of Formulas I, II, and III, i.e., (OR¹)ₓ—Si—(NR²R³)₄₋ₓ, (NR¹R²)ₙ(OR³)₃₋ₙSi—Si(OR⁴)₃₋ₘ(NR⁵R⁶)ₘ, and (NR¹R²)ₙ(OR³)₃₋ₙSi—X—Si(OR⁴)₃₋ₘ (NR⁵R⁶)ₘ, respectively. These methods are now discussed.

Beginning with monomeric alkoxyaminosilane complexes of Formula I, i.e., (OR¹)ₓ—Si—(NR²R³)₄₋ₓ, the reaction mechanism may proceed according to Example 1, which is presented immediately below.

### Example 1: General Reaction Mechanism for Monomeric Alkoxyaminosilane Complexes

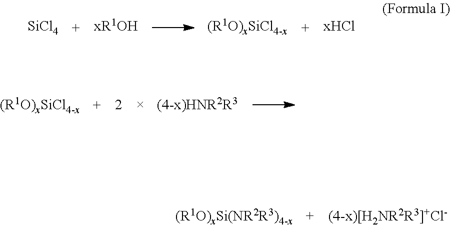

The method of synthesizing monomeric alkoxyaminosilane complexes of Formula I may include the steps of:
(A) loading a reactor with a solvent and SiCl₄,
(B) adding at least one equivalent of an alcohol of HOR¹ to the reactor,
(C) adding at least two equivalents of HNR²R³ to the reaction to yield a Cl⁻[H₂NR²R³]⁺ salt byproduct,
(D) removing the Cl⁻[H₂NR²R³]⁺ salt byproduct by filtration, and
(E) purifying the organometallic compound of Formula I by distillation.

Referring to the reaction mechanism of Example 1 and step (A), the reactor may be equipped with an HCl scrubber to neutralize the HCl byproduct. Suitable solvents for step (A) include those that are chemically inert with respect to the reaction reagents, byproducts, and the final product, and that possess a boiling point sufficiently different from that of the final product, whether higher or lower, to permit efficient recovery of the final product by distillation without interference. For example, suitable solvents for step (A) may include a hydrocarbon solvent selected from saturated aliphatic hydrocarbons, unsaturated aliphatic hydrocarbons having one or more carbon-carbon double or triple bonds, cyclic hydrocarbons (including cycloalkanes and cycloalkenes), and aromatic hydrocarbons, each having up to 60 carbon atoms, and mixtures thereof. Optionally, the solvent may include one or more atoms from group 14, 15 and 16. For example, suitable solvents for step (A) may include hexane, cyclohexane, heptane, n-dodecane, 1,3-diisopropylbenzene, or 1-octadecene. Step (A) may occur at or near room temperature, such as between 20° C. and 25° C. After step (A), the reactor may be cooled, such as to −10° C., 0° C., 5° C., or 10° C. Step (B) may take place during cooling to, e.g., 0° C. After step (B), the reactor may be heated to room temperature, such as from 20° C. to 25° C., or above, such as from 30° C. to 65° C. After step (B), the reaction mixture may be stirred or otherwise mixed for a period of 30 minutes, 1 hour, 1 and ½ hours, or 2 hours. The reaction mixture may be stirred or otherwise mixed for longer periods as needed, such as overnight. Step (C) may occur after this period of mixing. Although filtration and distillation are provided for steps (D) and (E), respectively, other separation and purification processes are contemplated, including chromatography, extraction, and evaporation.

Now turning to dimeric alkoxyaminosilane complexes of Formula II, (NR¹R²)ₙ(OR³)₃₋ₙSi—Si(OR⁴)₃₋ₘ(NR⁵R⁶)ₘ, the reaction mechanism may proceed according to Example 2, which is presented immediately below.

### Example 2: General Reaction Mechanism for Dimeric Alkoxyaminosilane Complexes

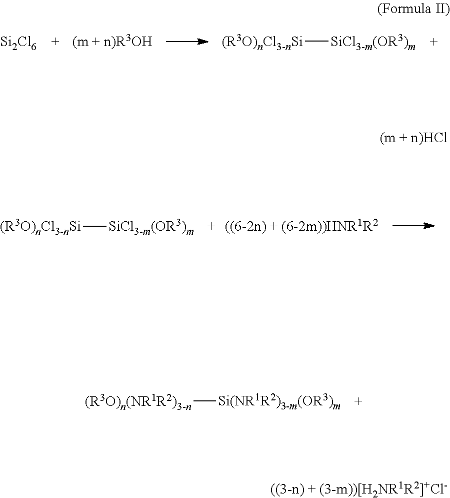

The method of synthesizing dimeric alkoxyaminosilane complexes of Formula II may include the steps of:
(A) loading a reactor with a solvent and Si₂Cl₆,
(B) adding at least one equivalent of an alcohol of HOR³ to the reactor,
(C) adding at least two equivalents of HNR¹R² to the reaction to yield a Cl⁻[H₂NR¹R²]⁺ salt byproduct,
(D) removing the Cl⁻[H₂NR¹R²]⁺ salt byproduct by filtration, and
(E) purifying the organometallic compound of Formula II by distillation.

Referring to the reaction mechanism of Example 2 and step (A), the reactor may be equipped with an HCl scrubber to neutralize the HCl byproduct. Suitable solvents for step (A) include those that are chemically inert with respect to the reaction reagents, byproducts, and the final product, and that possess a boiling point sufficiently different from that of the final product, whether higher or lower, to permit efficient recovery of the final product by distillation without interference. For example, suitable solvents for step (A) may include a hydrocarbon solvent selected from saturated aliphatic hydrocarbons, unsaturated aliphatic hydrocarbons having one or more carbon-carbon double or triple bonds, cyclic hydrocarbons (including cycloalkanes and cycloalkenes), and aromatic hydrocarbons, each having up to 60 carbon atoms, and mixtures thereof. Optionally, the solvent may include one or more atoms from group 14, 15 and 16. For example, suitable solvents for step (A) may include hexane, cyclohexane, heptane, n-dodecane, 1,3-diisopropylbenzene, or 1-octadecene. Step (A) may occur at or near room temperature, such as between 20° C. and 25° C. After step (A), the reactor may be cooled, such as to −10° C., 0° C., 5° C., or 10° C. Step (B) may take place during cooling to, e.g., 0° C. After step (B), the reactor may be heated to room temperature, such as from 20° C. to 25° C., or above, such as from 30° C. to 65° C. After step (B), the reaction mixture may be stirred or otherwise mixed for a period of 30 minutes, 1 hour, 1 and ½ hours, or 2 hours. The reaction mixture may be stirred or otherwise mixed for longer periods as needed, such as overnight. Step (C) may occur after this period of mixing. Although filtration and distillation are provided for steps (D) and (E), respectively, other separation and purification processes are contemplated, including chromatography, extraction, and evaporation.

Lastly, turning to dimeric alkoxyaminosilane complexes of Formula III, i.e., (NR¹R²)ₙ(OR³)₃₋ₙSi—X—Si(OR⁴)₃₋ₘ(NR⁵R⁶)ₘ, the reaction mechanism may proceed according to Example 3, which is presented immediately below.

### Example 3: General Reaction Mechanism for Dimeric Alkoxyaminosilane Complexes

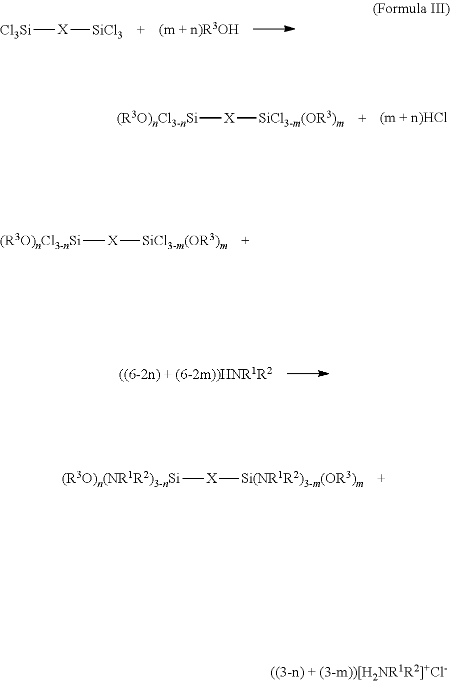

The method of synthesizing dimeric alkoxyaminosilane complexes of Formula III may include the steps of:
(A) loading a reactor with a solvent and Cl₃Si—X—SiCl₃,
(B) adding at least one equivalent of an alcohol of HOR³ to the reactor,
(C) adding at least two equivalents of HNR¹R² to the reaction to yield a Cl⁻[H₂NR¹R²]⁺ salt byproduct,
(D) removing the Cl⁻[H₂NR¹R²]⁺ salt byproduct by filtration, and
(E) purifying the organometallic compound of Formula III by distillation.

Referring to the reaction mechanism of Example 3 and step (A), the reactor may be equipped with an HCl scrubber to neutralize the HCl byproduct. Suitable solvents for step (A) include those that are chemically inert with respect to the reaction reagents, byproducts, and the final product, and that possess a boiling point sufficiently different from that of the final product, whether higher or lower, to permit efficient recovery of the final product by distillation without interference. For example, suitable solvents for step (A) may include a hydrocarbon solvent selected from saturated aliphatic hydrocarbons, unsaturated aliphatic hydrocarbons having one or more carbon-carbon double or triple bonds, cyclic hydrocarbons (including cycloalkanes and cycloalkenes), and aromatic hydrocarbons, each having up to 60 carbon atoms, and mixtures thereof. Optionally, the solvent may include one or more atoms from group 14, 15 and 16. For example, suitable solvents for step (A) may include hexane, cyclohexane, heptane, n-dodecane, 1,3-diisopropylbenzene, or 1-octadecene. Step (A) may occur at or near room temperature, such as between 20° C. and 25° C. After step (A), the reactor may be cooled, such as to −10° C., 0° C., 5° C., or 10° C. Step (B) may take place during cooling to, e.g., 0° C. After step (B), the reactor may be heated to room temperature, such as from 20° C. to 25° C., or above, such as from 30° C. to 65° C. After step (B), the reaction mixture may be stirred or otherwise mixed for a period of 30 minutes, 1 hour, 1 and ½ hours, or 2 hours. The reaction mixture may be stirred or otherwise mixed for longer periods as needed, such as overnight. Step (C) may occur after this period of mixing. Although filtration and distillation are provided for steps (D) and (E), respectively, other separation and purification processes are contemplated, including chromatography, extraction, and evaporation.

Having discussed general reaction mechanisms for organometallic compounds of Formulas I, II, and III and synthesis methods for same, non-limiting examples of syntheses of compounds within the scope of Formulas I, II, and III are now provided.

### Experiment 1: Synthesis of (MeQ)₂Si(NMe₂)₂

A 5 L jacketed reactor was loaded with n-dodecane and SiCl₄. The contents of the reactor were cooled to 0° C. The reactor was equipped with HCl scrubber to neutralize HCl byproduct. Two equivalents of MeOH were added to the reactor contents while cooling. Thereafter, the reaction mixture was heated to 22° C. The reaction mixture was stirred for 1 hour prior to the addition of 4 equivalents of HNMe₂ gas via bubbling though the reaction mixture. The [H₂NMe₂]⁺Cl⁻ salt byproduct was then removed from the final reaction mixture via filtration. The product was isolated and purified from the filtrate via distillation.

### Experiment 2: Synthesis of (MeO)₂Si(NEt₂)₂

A 5 L jacketed reactor was loaded with n-dodecane and SiCl₄. The contents of the reactor were cooled to 0° C. The reactor was equipped with HCl scrubber to neutralize HCl byproduct. Two equivalents of MeOH were added to the reactor contents while cooling. Thereafter, the reaction mixture was heated to 22° C. The reaction mixture was stirred for 1 hour prior to a drop-wise addition of 4 equivalents of HNEt₂. The [H₂NEt₂]⁺Cl⁻ salt byproduct was then removed from the final reaction mixture via filtration. The product was isolated and purified from the filtrate via distillation.

### Experiment 3: Synthesis of (MeO)Si(NEtMe)₃

A 5 L jacketed reactor was loaded with n-dodecane and SiCl₄. The contents of the reactor were cooled to 0° C. The reactor was equipped with HCl scrubber to neutralize HCl byproduct. One equivalent of MeOH was added to the reactor contents while cooling. Thereafter, the reaction mixture was heated to 22° C. The reaction mixture was stirred for 1 hour prior to a drop-wise addition of 6 equivalents of HNEtMe. The [H₂NEtMe]⁺Cl⁻ salt byproduct was then removed from the final reaction mixture via filtration. The product was isolated and purified from the filtrate via distillation.

### Experiment 4: Synthesis and Analysis of (iPrO)₂Si(NEt₂)₂

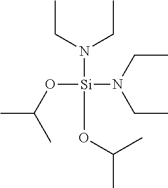 [SMILES: CCN(CC)[Si](OC(C)C)(OC(C)C)N(CC)CC]

A round bottom flask was loaded with n-dodecane and SiCl₄. The contents of the flask were cooled to 0° C. The system was equipped with HCl scrubber to neutralize HCl byproduct. Two equivalents of iPrOH were added to the reaction contents while cooling. Thereafter, the reaction mixture was heated to 22° C. The reaction mixture was stirred for 1 hour prior to a drop-wise addition of 4 equivalents of HNEt₂. The [H₂NEt₂]⁺Cl⁻ salt byproduct was then removed from the final reaction mixture via filtration. The product was isolated and purified from the filtrate via distillation.

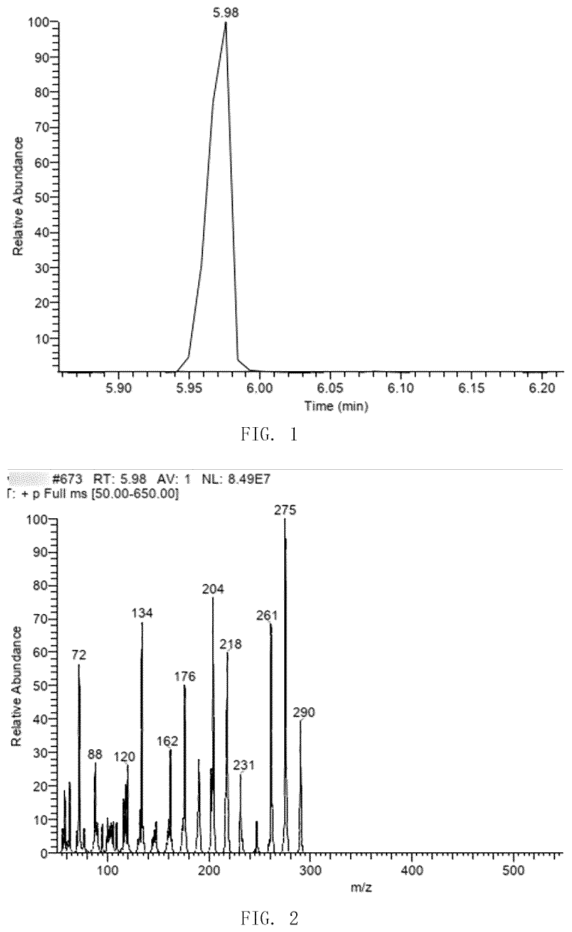

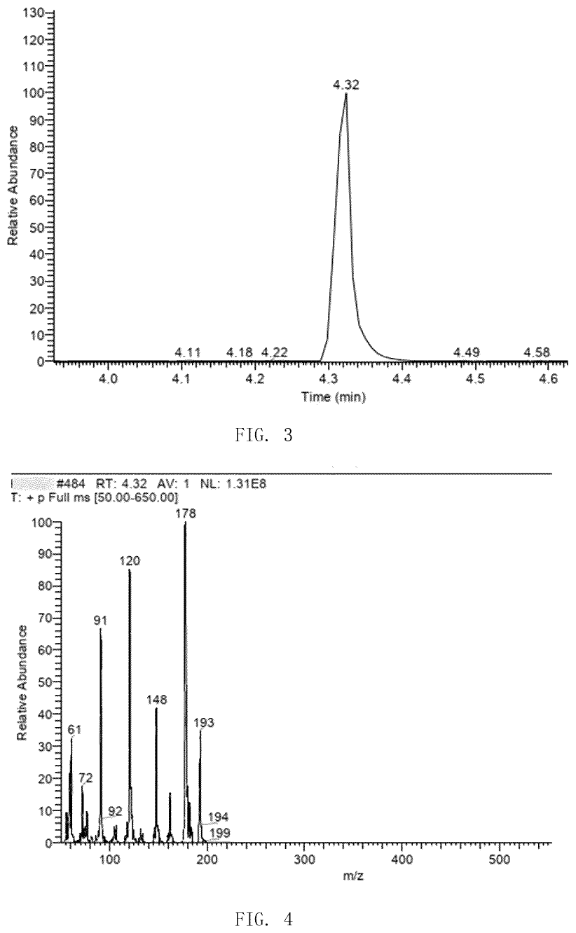

Referring to FIGS. 1 and 2, the product was confirmed to be (iPrO)₂Si(NEt₂)₂ using gas chromatography and mass spectroscopy. Referring to FIG. 1, the product eluted at 5.98 minutes. FIG. 2 depicts a parent ion at m/z 290, with characteristic fragment ions at m/z 275, 261, 218 and 204.

### Experiment 5: Synthesis and Analysis of (MeO)₃Si(NEt₂)

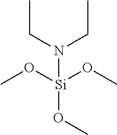

A round bottom flask was loaded with 1,3-diisopropylbenzene and SiCl₄. The contents of the flask were cooled to 0° C. The system was equipped with HCl scrubber to neutralize HCl byproduct. Three equivalents of MeOH were added to the reaction contents while cooling. Thereafter, the reaction mixture was heated to 22° C. The reaction mixture was stirred for 1 hour prior to a drop-wise addition of 2 equivalents of HNEt₂. The [H₂NEt₂]⁺Cl⁻ salt byproduct was then removed from the final reaction mixture via filtration. The product was isolated and purified from the filtrate via distillation.

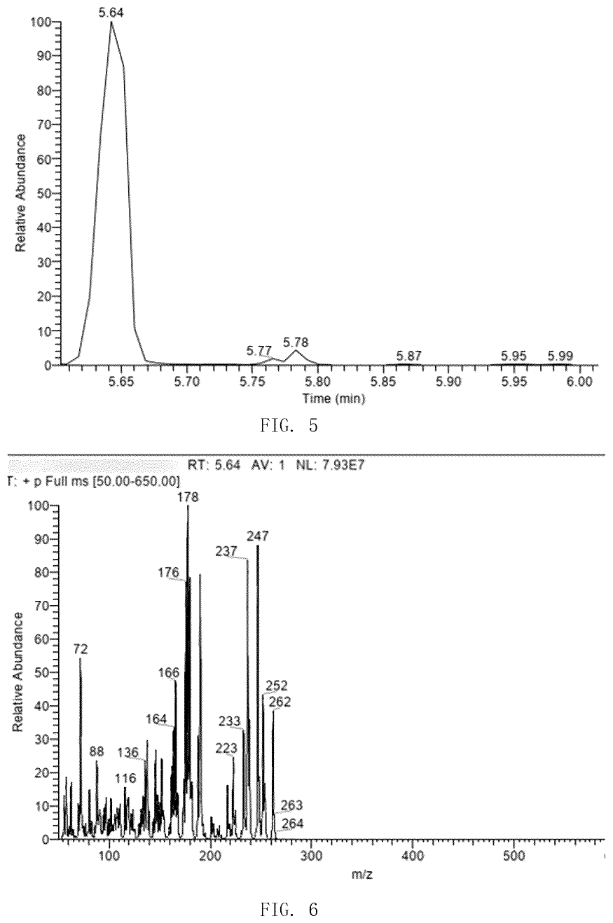

Referring to FIGS. 3 and 4, the product was confirmed to be (MeO)₃Si(NEt₂) using gas chromatography and mass spectroscopy. Referring to FIG. 3, the product eluted at 4.32 minutes. FIG. 4 depicts a parent ion at m/z 193, with characteristic fragment ions at m/z 178, 120, and 91.

### Experiment 6: Synthesis and Analysis of (EtO)₂Si(NEt₂)₂

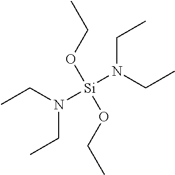 [SMILES: CCO[Si](OCC)(N(CC)CC)N(CC)CC]

A round bottom flask was loaded with hexane and SiCl₄. The contents of the flask were cooled to 0° C. The system was equipped with HCl scrubber to neutralize HCl byproduct. Two equivalents of EtOH were added to the reaction contents while cooling. Thereafter, the reaction mixture was heated to 22° C. The reaction mixture was stirred for 1 hour prior to a drop-wise addition of 4 equivalents of HNEt₂. The [H₂NEt₂]⁺Cl⁻ salt byproduct was then removed from the final reaction mixture via filtration. The product was isolated and purified from the filtrate via distillation.

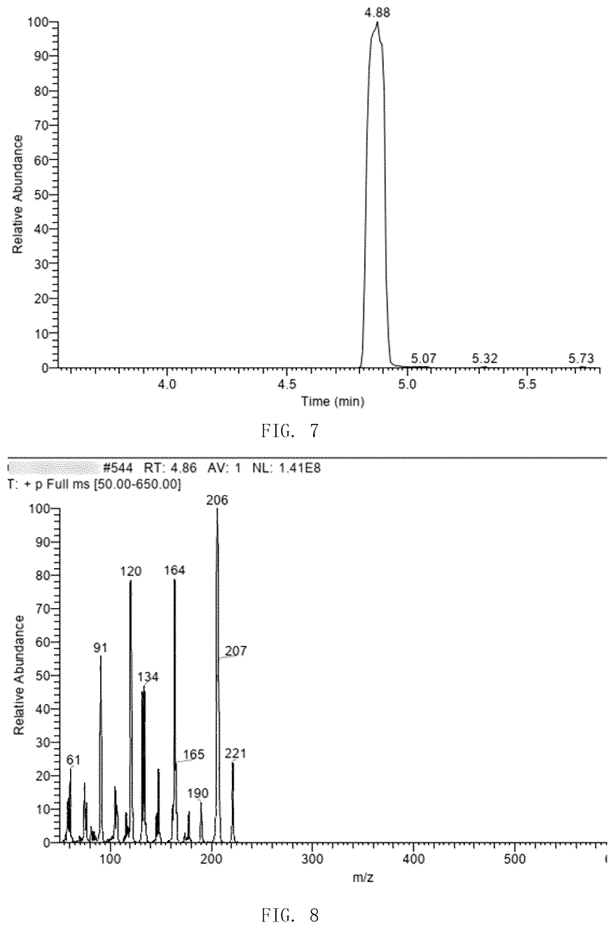

Referring to FIGS. 5 and 6, the product was confirmed to be (EtO)₂Si(NEt₂)₂ using gas chromatography and mass spectroscopy. Referring to FIG. 5, the product eluted at 5.64 minutes. FIG. 6 depicts a parent ion at m/z 262, with characteristic fragment ions at m/z 247, 237, and 178.

### Experiment 7: Synthesis and Analysis of (MeO)₃Si(N(iPr)₂)

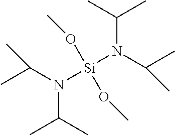 [SMILES: CO[Si](OC)(N(C(C)C)C(C)C)N(C(C)C)C(C)C]

A round-bottom flask was loaded with n-hexane and SiCl₄. The contents of the flask were cooled to 0° C. The system was equipped with HCl scrubber to neutralize HCl byproduct. Three equivalents of MeOH were added to the reaction contents while cooling. Thereafter, the reaction mixture was heated to 22° C. The reaction mixture was stirred overnight prior to a dropwise addition of 4 equivalents of HN(iPr)₂ to the reaction mixture. The [H₂N(iPr)₂]⁺Cl⁻ salt byproduct was then removed from the final reaction mixture via filtration. The product was isolated and purified from the filtrate via distillation.

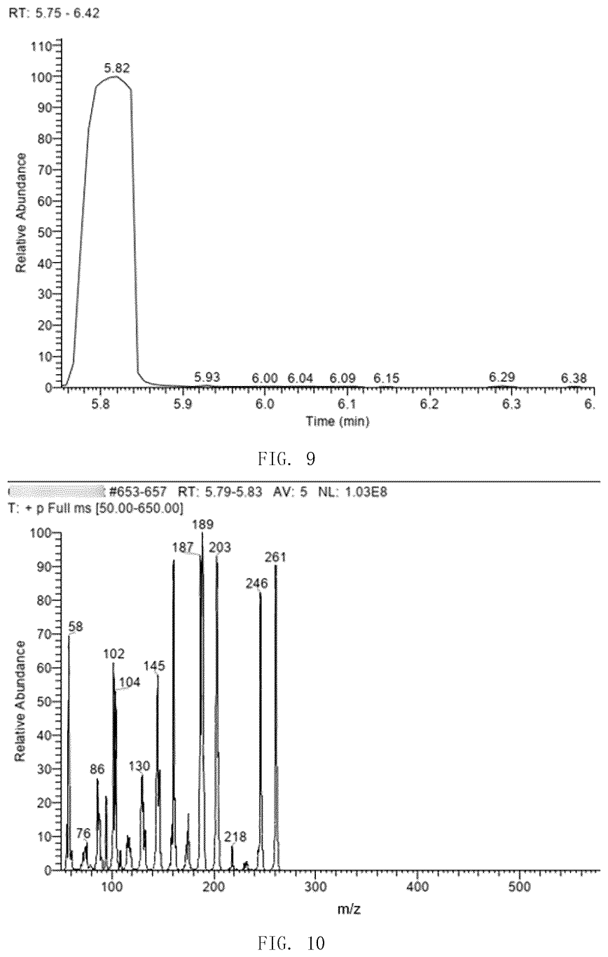

Referring to FIGS. 7 and 8, the product was confirmed to be (MeO)₃Si(N(iPr)₂) using gas chromatography and mass spectroscopy. Referring to FIG. 7, the product eluted at 4.88 minutes. FIG. 8 depicts a parent ion at m/z 221, with characteristic fragment ions at m/z 206, 164, 120, and 91.

### Experiment 8: Synthesis and Analysis of (iPrO)Si(NEtMe)₃

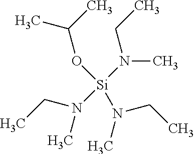 [SMILES: CCN(C)[Si](OC(C)C)(N(C)CC)N(C)CC]

A round-bottom flask was loaded with n-hexane and SiCl₄. The contents of the flask were cooled to 0° C. The system was equipped with HCl scrubber to neutralize HCl byproduct. One equivalent of iPrOH was added to the reaction contents while cooling. Thereafter, the reaction mixture was heated to 22° C. The reaction mixture was stirred overnight prior to a dropwise addition of 6 equivalents of HNEtMe to the reaction mixture. The [H₂NEtMe]⁺Cl⁻ salt byproduct was then removed from the final reaction mixture via filtration. The product was isolated and purified from the filtrate via distillation.

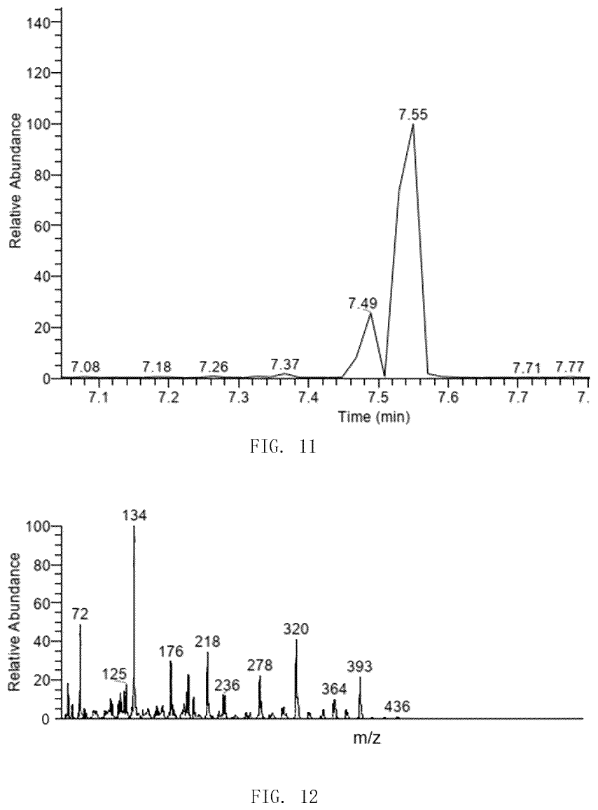

Referring to FIGS. 9 and 10, the product was confirmed to be (iPrO)Si(NEtMe)₃ using gas chromatography and mass spectroscopy. Referring to FIG. 9, the product eluted at 5.82 minutes. FIG. 10 depicts a parent ion at m/z 261, with characteristic fragment ions at m/z 246, 203, 189, and 145.

### Experiment 9: Synthesis and Analysis of (iPrO)₂(NEt₂)Si—Si(NEt₂)(OiPr)₂

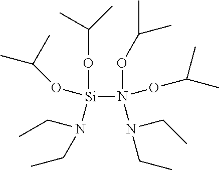

A round-bottom flask was loaded with n-hexane and Si₂Cl₆. The contents of the flask were cooled to 0° C. The system was equipped with HCl scrubber to neutralize HCl byproduct. Four equivalents of iPrOH were added to the reaction contents while cooling. Thereafter, the reaction mixture was heated to 22° C. The reaction mixture was stirred overnight prior to a dropwise addition of 4 equivalents of HNEt₂ to the reaction mixture. The [H₂NEt₂]⁺Cl⁻ salt byproduct was then removed from the final reaction mixture via filtration. The product was isolated and purified from the filtrate via distillation.

Referring to FIGS. 11 and 12, the product was confirmed to be (iPrO)₂(NEt₂) Si—Si(NEt₂)(OiPr)₂ using gas chromatography and mass spectroscopy. Referring to FIG. 11, the product eluted at 7.55 minutes. FIG. 12 depicts a parent ion at m/z 436, with characteristic fragment ions at m/z 393, 320, 278, 218, 134, and 72.

As mentioned at the outset, monomeric alkoxyaminosilane complexes of Formula I: (OR¹)ₓ—Si—(NR²R³)₄₋ₓ, and dimeric alkoxyaminosilane complexes of Formulas II: (NR¹R²)ₙ(OR³)₃₋ₙSi—Si(OR⁴)₃₋ₘ(NR⁵R⁶)ₘ and III: (NR¹R²)ₙ(OR³)₃₋ₙSi—X—Si(OR⁴)₃₋ₘ (NR⁵R⁶)ₘ may have utility as precursors for the deposition of SiO₂ and SiₓN_{y} (x and y are independently selected integers from 1 to 6) via vapor deposition processes, such as chemical vapor deposition (CVD), plasma enhanced chemical vapor deposition (PECVD), atomic layer deposition (ALD), and plasma enhanced atomic layer deposition (PEALD). The deposition of a metal oxide film or a metal nitride film by a vapor phase deposition process may proceed as follows:
(A) providing at least one substrate having functional O—H groups covering the surface,
(B) delivering to said substrate at least one compound of Formula I, II, or III,
(C) purging the substrate with purge gas,
(D) delivering to said substrate an oxygen source or a nitrogen source in the gaseous or plasma phase,
(E) purging the substrate with purge gas,
(F) repeating steps (B) through (E) until a desired thickness of metal oxide has been deposited.

For example, SiO₂ films may be deposited by an ALD process as follows:
(A) providing at least one substrate having functional O—H groups covering the surface,
(B) delivering to said substrate at least one compound of Formula I, II, or III in the gaseous phase;
(C) purging the substrate with purge gas,
(D) delivering to said substrate an oxygen source in the gaseous phase,
(E) purging the substrate with purge gas,
(F) repeating steps (B) through (E) until a desired thickness of metal oxide has been deposited.

An SiO₂ film may deposited by a CVD process as follows:
(A) providing a suitable substrate
(B) delivering to said substrate at least one compound of Formula I, II, or III in the gaseous phase;
(C) delivering to said substrate an oxygen source in the gaseous phase,
(D) maintaining a suitable temperature and pressure to promote the surface reaction
(E) repeating steps (B) and (C) either via pulse of (B) or a continuous flow until a desired thickness of metal oxide has been deposited.

Oxygen sources may include compounds such as H₂O in gaseous phase, H₂O₂ in gaseous phase, O₂, and O₃. Nitrogen sources may include compounds such as NH₃, N₂, hydrazine, and plasma-activated nitrogen.

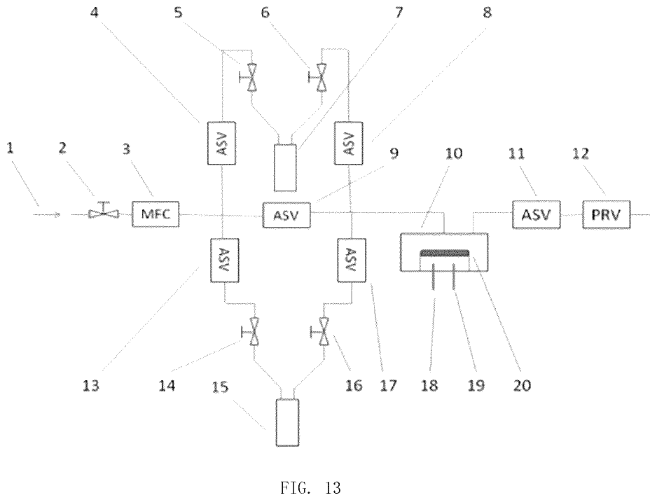

FIG. 13 depicts a schematic for an ALD system. For the half cycle of precursor A reaction, an inert carrier gas 1 such as Ar is passed through manual valve 2 and mass flow controller 3 at a controlled flow rate to a first bubbler 7 containing precursor A and carries vaporized precursor A to the reaction chamber 10. The automatic switch valves (ASV) 4 and 8 for bubbler 7 open automatically for the period of time that is pre-set. ASV 4 and 8 then close automatically, followed by purging and vacuuming of the reaction chamber for a pre-set period of time. The half cycle reaction for precursor A is finished. Automatically, ASV 13 and 17 open, an inert carrier gas 1 such as Ar is passed through manual valve 2 and mass flow controller 3 at a controlled flow rate to a second bubbler 15 containing precursor B and carries vaporized precursor B to the reaction chamber 10. After the pre-set period of time, ASV 13 and 17 close automatically, followed by purging and vacuuming of the reaction chamber for a pre-set period of time. The half cycle reaction for precursor B is finished. A full reaction cycle is finished, i.e. one atomic layer of product is deposited on substrate 20. The cycle is repeated to obtain the desired thickness. The temperature is controlled by a heater 18 and thermocouple 19. The pressure in the reaction chamber is controlled by pressure regulating valve 12, which is connected to vacuum pump.

1-8. (canceled)

9. An organometallic compound of Formula II: 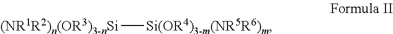
wherein
R¹, R², R³, R⁴, R⁵, and R⁶ are independently selected from the group consisting of H and an acyclic or a cyclic alkyl group having from 1 to 10 carbon atoms, and
n is an integer from 0 to 3 and m is an integer from 1 to 3.

10. The organometallic compound of claim 9, wherein R¹, R², R³, R⁴, R⁵, and R⁶ are acyclic alkyl groups having from 1 to 4 carbon atoms.

11. The organometallic compound of claim 9, wherein R³ and R⁴ are isopropyl.

12. The organometallic compound of claim 9, wherein R¹, R², R³, and R⁴ are methyl or ethyl.

13. The organometallic compound of claim 9, wherein R¹ and R² are different, and R³ and R⁴ are different.

14. The organometallic compound of claim 9, wherein m and n are 2.

15. An organometallic compound of Formula III: 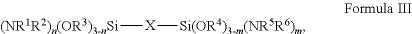
R¹, R², R³, R⁴, R⁵, and R⁶ are independently selected from the group consisting of H and an acyclic or a cyclic alkyl group having from 1 to 10 carbon atoms,
n is an integer from 0 to 3 and m is an integer from 1 to 3,
X is selected from the group consisting of O, NR⁷, CO, COO, CO(CR⁷R⁸)_{y}, and (CR⁷R⁸)_{y},
R⁷ and R⁸ are independently selected from the group consisting of H and an acyclic or a cyclic alkyl group having from 1 to 10 carbon atoms, and
y is an integer from 1 to 6.

16. The organometallic compound of claim 15, wherein R¹, R², R³, R⁴, R⁵, and R⁶ are acyclic alkyl groups having from 1 to 4 carbon atoms.

17. The organometallic compound of claim 15, wherein R¹, R², R³, and R⁴ are methyl or ethyl.

18. The organometallic compound of claim 15, wherein R¹ and R² are different, and R³ and R⁴ are different.

19. The organometallic compound of claim 15, wherein m and n are 2.

20. The organometallic compound of claim 15, wherein X is selected from the group consisting of O, NR⁷, CO.

21. A method of forming a metal oxide film or a metal nitride film by a vapor phase deposition process, comprising:
(A) providing at least one substrate having functional O—H groups covering the surface,
(B) delivering to said substrate at least one compound of Formula II in the gaseous phase: 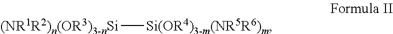
wherein
R¹, R², R³, R⁴, R⁵, and R⁶ are independently selected from the group consisting of H and an acyclic or a cyclic alkyl group having from 1 to 10 carbon atoms, and
n is an integer from 0 to 3 and m is an integer from 1 to 3,
(C) purging the substrate with purge gas,
(D) delivering to said substrate an oxygen source or a nitrogen source in the gaseous or plasma phase,
(E) purging the substrate with purge gas,
(F) repeating steps (B) through (E) until a desired thickness of metal oxide has been deposited.

22. A method of forming a metal oxide film or a metal nitride film by a vapor phase deposition process, comprising:
(A) providing at least one substrate having functional O—H groups covering the surface,
(B) delivering to said substrate at least one compound of Formula III in the gaseous phase: 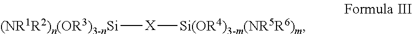
wherein
R¹, R², R³, R⁴, R⁵, and R⁶ are independently selected from the group consisting of H and an acyclic or a cyclic alkyl group having from 1 to 10 carbon atoms,
n is an integer from 0 to 3 and m is an integer from 1 to 3,
X is selected from the group consisting of O, NR⁷, CO, COO, CO(CR⁷R⁸)_{y}, and (CR⁷R⁸)_{y},
R⁷ and R⁸ are independently selected from the group consisting of H and an acyclic or a cyclic alkyl group having from 1 to 10 carbon atoms, and
y is an integer from 1 to 6,
(C) purging the substrate with purge gas,
(D) delivering to said substrate an oxygen source or a nitrogen source in the gaseous or plasma phase,
(E) purging the substrate with purge gas,
(F) repeating steps (B) through (E) until a desired thickness of metal oxide has been deposited.

23-24. (canceled)

25. The method of claim 21, wherein R¹, R², R³, R⁴, R⁵, and R⁶ are acyclic alkyl groups having from 1 to 4 carbon atoms.

26. The method of claim 21, wherein R³ and R⁴ are isopropyl.

27. The method of claim 21, wherein R¹, R², R³, and R⁴ are methyl or ethyl.

28. The method of claim 21, wherein R¹ and R² are different, and R³ and R⁴ are different.

29. The method of claim 21, wherein m and n are 2.

30. The method of claim 22, wherein R¹, R², R³, R⁴, R⁵, and R⁶ are acyclic alkyl groups having from 1 to 4 carbon atoms.

31. The method of claim 22, wherein R¹, R², R³, and R⁴ are methyl or ethyl.

32. The method of claim 22, wherein R¹ and R² are different, and R³ and R⁴ are different.

33. The method of claim 22, wherein m and n are 2.

34. The method of claim 22, wherein X is selected from the group consisting of O, NR⁷, CO.
